(19) United States
(12) Patent Application Publication
(10) Pub. No.: US 2024/0422923 A1
(43) Pub. Date: Dec. 19, 2024

(54) DISPLAY DEVICE

(71) Applicant: Samsung Display Co., LTD., Yongin-si (KR)

(72) Inventor: SUNGWON KIM, Yongin-si (KR)

(21) Appl. No.: 18/612,319

(22) Filed: Mar. 21, 2024

(30) Foreign Application Priority Data
Jun. 16, 2023 (KR) 10-2023-0077275

(51) Int. Cl. H05K 5/02; H10K 59/80; H10K 102/00

(52) U.S. Cl. CPC H05K 5/0217; H10K 59/873; H10K 59/8791; H10K 2102/311

(57) ABSTRACT

A display device includes a display module, a plate including a base portion, and a first sidewall and a second sidewall protruding downward from the base portion to face each other, and disposed under the display module, chain units disposed between the first sidewall and the second sidewall to be spaced apart from each other along a first direction, each extending along a second direction crossing the first direction to be coupled to the first sidewall and the second sidewall, and a roller including bumps inserted between the chain units disposed adjacent to each other, and overlapping the base portion. The display module overlapping the base portion, the base portion, the first sidewall, and the second sidewall are bent with respect to the roller.

This application claims priority to Korean Patent Application No. 10-2023-0077275, filed on Jun. 16, 2023, and all the benefits accruing therefrom under 35 U.S.C. § 119, the content of which in its entirety is herein incorporated by reference.

### BACKGROUND

### 1. Field

The invention relates to a display device, and more particularly, to a display device capable of performing a sliding operation.

### 2. Description of Related Art

A display device such as a smartphone, a notebook computer, a navigation system, or a smart television supplies an image to a user through a display screen. The display device may include a display panel that generates the image.

Recently, display devices having various forms are being developed with technology development. For example, flexible display devices capable of folding or rolling are being developed. The flexible display devices, the shapes of which may be variously changed, are easy to carry and thus improve the convenience to a user.

An expandable, flexible display device among the flexible display devices may accommodate at least a portion in a case, or draw at least a portion of the display device out of the case as needed by using the folding characteristics of a display module. Accordingly, a user may expand a display screen as needed.

### SUMMARY

An embodiment of the invention provides a display device in which an indentation of a surface of a display module is minimally viewed, and thus surface quality is improved and a structure of a sliding portion is simplified.

An embodiment of the invention provides a display device including a display module, a plate including a base portion, and a first sidewall and a second sidewall protruding downward from the base portion to face each other, and disposed under the display module, chain units disposed between the first sidewall and the second sidewall to be spaced apart from each other and directed along a first direction, and each extending along a second direction crossing the first direction to be coupled to the first sidewall and the second sidewall, and a roller including bumps inserted between the chain units and disposed adjacent to each other, and overlapping the base portion, wherein the display module overlapping the base portion, the base portion, the first sidewall, and the second sidewall are bent with respect to the roller.

In an embodiment, the chain units may each include a coupling portion which extends in the second direction and in which a chain groove is defined, and a pin which is inserted into the chain groove, and of which one end and the other end are opposed to each other in the second direction and protrude from the coupling portion.

In an embodiment, the first sidewall and the second sidewall may respectively include pin holes of which at least a portion is penetrated, and into which the one end and the other end of each of the chain units are inserted.

In an embodiment, the pin may further include a first fixing portion inserted into the pin hole of the first sidewall to fix the one end with the first sidewall, and a second fixing portion inserted into the pin hole of the second sidewall to fix the other end with the second sidewall.

In an embodiment, the pin may have either a circular or a polygonal shape on a cross-section, and the pin holes and the chain groove may have a shape corresponding to the shape of the pin.

In an embodiment, the coupling portion may include a first guide portion disposed adjacent to the one end, a second guide portion disposed adjacent to the other end, and a central portion disposed between the first guide portion and the second guide portion, wherein a width of the central portion in the second direction may be greater than a width of the first guide portion and a width of the second guide portion.

In an embodiment, the bumps may be inserted between the central portions to be disposed along a circumference of the roller.

In an embodiment, the first guide portion and the second guide portion may be in contact with a rear surface of the base portion, and the central portion may not be in contact with the rear surface.

In an embodiment, the coupling portion may include guide portions spaced apart from each other in the second direction, and central portions disposed between the guide portions to be disposed adjacent to each other in the second direction, wherein the bumps may be arranged apart from each other along the second direction and disposed adjacent to a circumference of the roller, wherein the bumps may be respectively inserted between the central portions to be disposed along the circumference of the roller.

In an embodiment, when the roller rotates, the coupling portion disposed between the bumps may rotate in the pin.

In an embodiment, the chain units may each include coupling portions which include a first guide portion, a second guide portion, and a central portion disposed between the first guide portion and the second guide portion, and in which a chain groove is defined, and a pin which is inserted into the chain groove, wherein the coupling portions may be spaced apart from each other along the second direction, and wherein the pin may be exposed between the coupling portions to be disposed adjacent to each other in the second direction.

In an embodiment, a width of each of the bumps in the second direction may be equal to or smaller than a width of the central portion in the second direction.

In an embodiment, when the roller rotates, a portion bent by the roller among the base portion, a display module overlapping the base portion, the first sidewall and the second sidewall may be changeable.

In an embodiment, the bumps may have either a triangular shape or a trapezoidal shape on a cross-section.

In an embodiment, the base portion, the first sidewall, and the second sidewall may be integrally provided.

In an embodiment, the display module may include an electronic panel including a display panel configured to supply an image, an input sensing portion configured to sense an external input, an anti-reflective layer disposed on the input sensing portion, an impact-absorbing layer disposed on the electronic panel, a window disposed on the impact-absorbing layer, and a panel protection layer disposed under the electronic panel.

In an embodiment, when the roller rotates to change from a first mode to a second mode, an area of the display module may increase, wherein the number of chain units disposed adjacent to the window in the second mode may be greater than the number of chain units disposed adjacent to the window in the first mode.

In an embodiment, the display device may further include a flexible circuit board connected to an end of the display module and a driving chip connected to the flexible circuit board, wherein a portion to which the flexible circuit board of the display module is connected may be bent to face a rear surface of the plate.

In an embodiment, the display device may further include an adhesive layer disposed between the display module and the plate, wherein the adhesive layer may be any one of a pressure sensitive adhesive (PSA) or an optically clear adhesive (OCA).

In an embodiment, the plate may include stainless steel.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of a display device, according to an embodiment;

FIG. 1B is a perspective view of a display device, according to an embodiment;

FIG. 2A is a cross-sectional view of a display device taken along I-I′ in FIG. 1A, according to an embodiment;

FIG. 2B is a cross-sectional view of a display device taken along II-II′ in FIG. 1B, according to an embodiment;

FIG. 3 is a cross-sectional view of a display module, according to an embodiment;

FIG. 4 is a cross-sectional view of an electronic panel, according to an embodiment;

FIG. 5 is a cross-sectional view of a display panel, according to an embodiment;

FIG. 6 is a plan view of a display panel, according to an embodiment;

FIG. 7A is an exploded perspective view of a display device, according to an embodiment;

FIG. 7B is a plan view illustrating a coupling relationship between a plate and chain units, according to an embodiment;

FIG. 8A is a perspective view illustrating a configuration of a display device, according to an embodiment;

FIG. 8B is a perspective view illustrating a configuration of a display device, according to an embodiment;

FIG. 9 is a perspective view illustrating a chain unit, according to an embodiment;

FIG. 10A is an exploded perspective view of a display device, according to an embodiment;

FIG. 10B is a plan view illustrating a coupling relationship between a plate and chain units, according to an embodiment;

FIG. 11A is a perspective view of a chain unit, according to an embodiment;

FIG. 11B is an exploded perspective view of a pin, according to an embodiment;

FIG. 12A is a perspective view illustrating a configuration of a display device,

according to an embodiment;

FIG. 12B is a cross-sectional view illustrating an arrangement relationship between a roller and a plate, according to an embodiment;

FIG. 13 is a cross-sectional view illustrating an arrangement relationship between a roller and a plate, according to an embodiment; and

FIG. 14 is a perspective view illustrating an arrangement relationship between a roller and a plate, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when a component (or region, layer, portion, etc.) is referred to as “on”, “connected”, or “coupled” to another component, it means that it is placed/connected/coupled directly on the other component or a third component can be disposed between them.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology and should not be interpreted as too ideal or too formal unless explicitly defined herein.

Hereinafter, embodiments of the invention will be described with reference to the accompanying drawings.

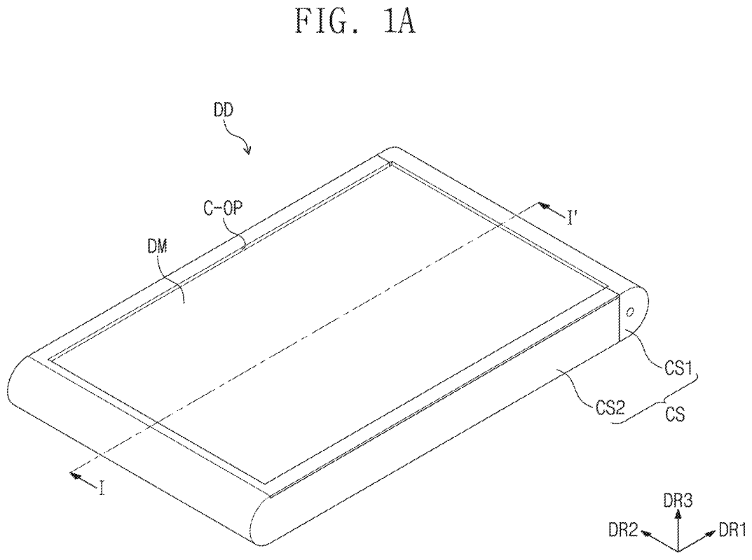

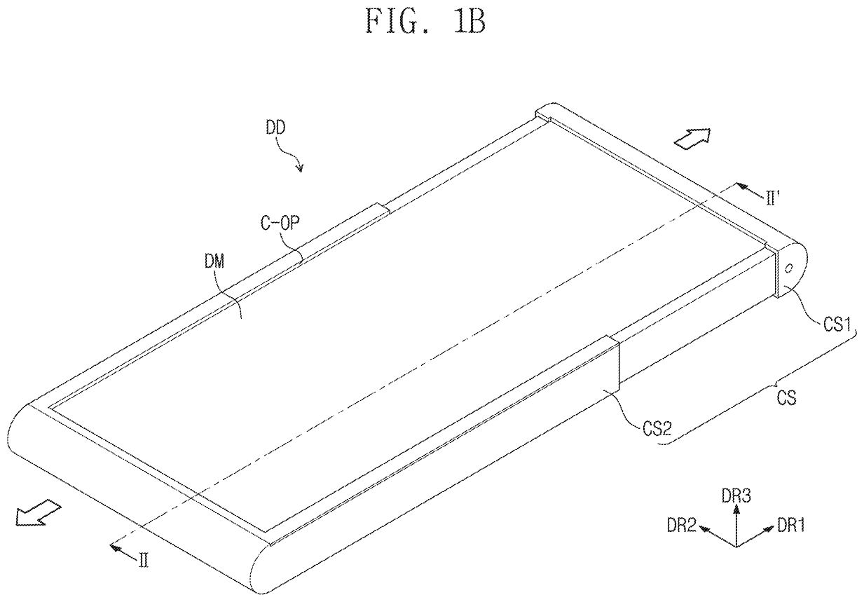

FIG. 1A is a perspective view of a display device, according to an embodiment. FIG. 1B is a perspective view of the display device, according to an embodiment. FIG. 1A is a perspective view of a display device DD that operates in a first mode, and FIG. 1B is a perspective view of the display device DD that operates in a second mode.

In an embodiment, the display device DD may be activated in response to an electrical signal, and display an image. The display device DD may include various examples. For example, the display device DD may be not only a large-sized device such as a television or a billboard, but also a small-and medium-sized device such as a monitor, a smartphone, a tablet computer, a navigation system or a game console. In an embodiment, a smartphone capable of performing a sliding operation is exemplarily illustrated as the display device DD. However, the invention is not limited thereto, and as long as including a flexible display module such as a rollable display device, the display device DD is not limited to any one embodiment.

In an embodiment and referring to FIGS. 1A and 1B, the display device DD may include a display module DM and a case CS in which the display module DM is accommodated. At least a portion of the display module DM may be exposed to the outside through a display opening C-OP defined in an upper portion of the case CS.

In an embodiment, the case CS may include a first case CS1 and a second case CS2. The first case CS1 and the second case CS2 may be coupled to each other to accommodate the display module DM. The first case CS1 may be coupled to the second case CS2 to be movable along a direction parallel to a first direction DR1. According to a usage state of a user, the first case CS1 may be coupled to the second case CS2 to move closer to or farther away from the second case CS2.

In an embodiment, a display surface of the display module DM exposed by the display opening C-OP may be directed parallel to each of the first direction DR1, and a second direction DR2 crossing the first direction DR1. The display module DM may display an image, toward a third direction DR3, on the display surface which is directed parallel to the first direction DR1 and the second direction DR2.

In the present disclosure, the third direction DR3 may be defined as a direction substantially perpendicular to a plane defined by the first direction DR1 and the second direction DR2. In an embodiment, a front surface (or upper surface) and a rear surface (or lower surface) of each member constituting the display device DD may be opposed to each other in the third direction DR3, and a normal direction of each of the front surface and the rear surface may be substantially parallel to the third direction DR3. A distance between the front surface and the rear surface, which are defined along the third direction DR3, may correspond to a thickness of a member (or unit).

In the present disclosure, the wording “on a plane” may be defined as a state of being viewed in the third direction DR3. In the present disclosure, the wording “on a cross-section” may be defined as a state of being viewed in the first direction DR1 or the second direction DR2. Meanwhile, directions indicated by the first to third directions DR1, DR2, and DR3 are relative concepts and may be changed to other directions.

In an embodiment and referring to FIGS. 1A and 1B, an area of the display surface of the display module DM exposed by the display opening C-OP of the case CS may be changeable according to the movement of the first case CS1 relative to the second case CS2. As the first case CS1 becomes farther away from the second case CS2, an opening area of the display opening C-OP may be greater in the first direction DR1.

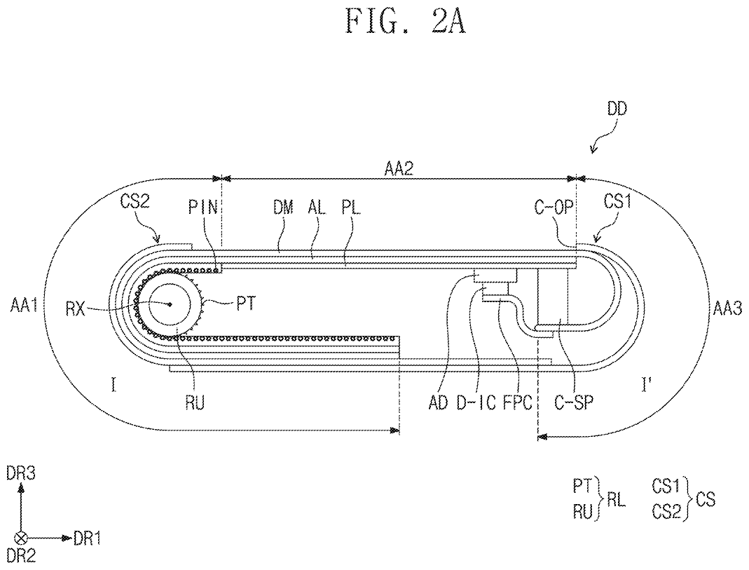

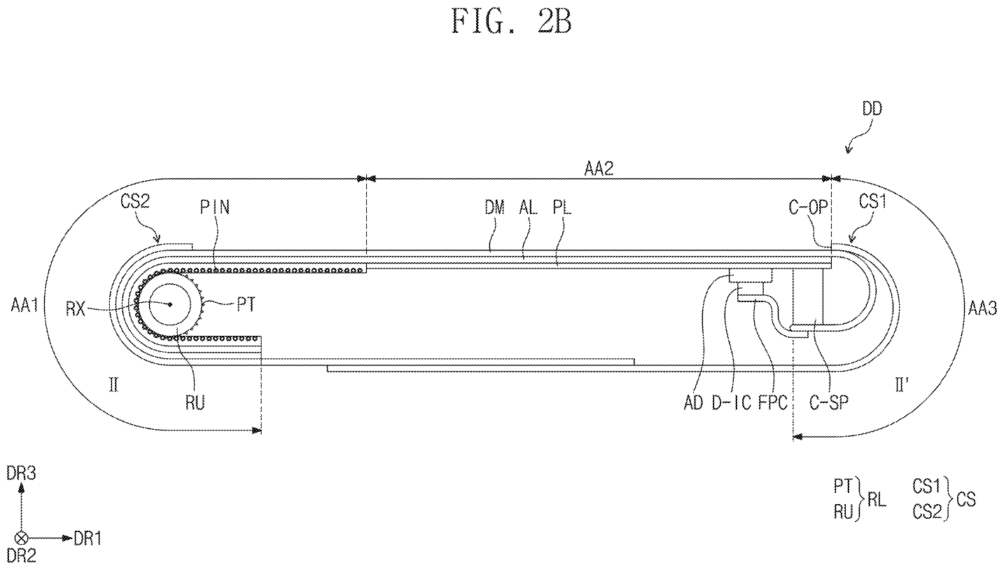

In an embodiment, the display module DM may be a flexible display module. The display module DM may be supported by a support plate PL (see FIG. 2A) disposed under the display module DM, and the area of the display surface viewed to a user may be changed by a roller RL (see FIG. 2A).

In the present disclosure, a state in which an area of the display module DM viewed to a user decreases may be defined as ‘a first mode’. In an embodiment, in one state of the first mode, the area of the display module DM viewed to a user may be the smallest. In addition, a state in which the area of the display module DM viewed to a user increases may be defined as ‘a second mode’. In one state of the second mode, the area of the display module DM viewed to a user may be the largest.

In an embodiment, mode changing of the first mode and the second mode in the display device DD may be performed by moving the first case CS1 in the first direction DR1 relative to the second case CS2 in a state in which at least any one of the first case CS1 or the second case CS2 is grasped, or remote control by a separate motor, or the like, and is not limited to any one embodiment.

FIG. 2A is a cross-sectional view of a display device taken along I-I′ in FIG. 1A, according to an embodiment. FIG. 2B is a cross-sectional view of the display device taken along II-II′ in FIG. 1B, according to an embodiment.

In an embodiment and referring to FIGS. 2A and 2B, the display device DD may include a case CS, a display module DM, a roller RL, and a support module which are accommodated in the case CS, where the support module is disposed under the display module DM to support the display module DM. The support module may guide the change of the shape of the display module DM while a sliding operation is repeated.

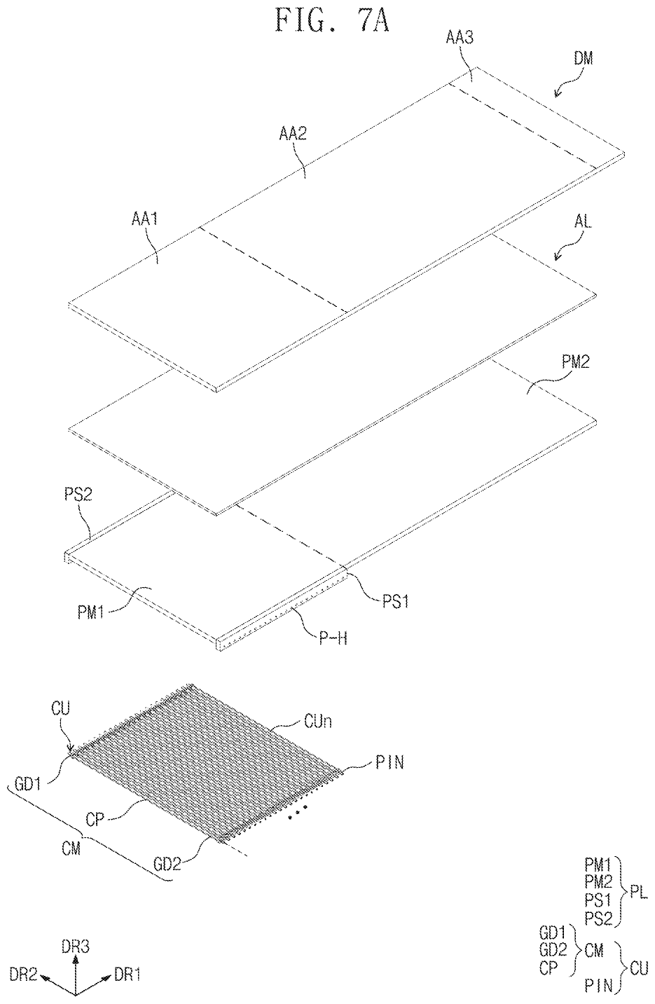

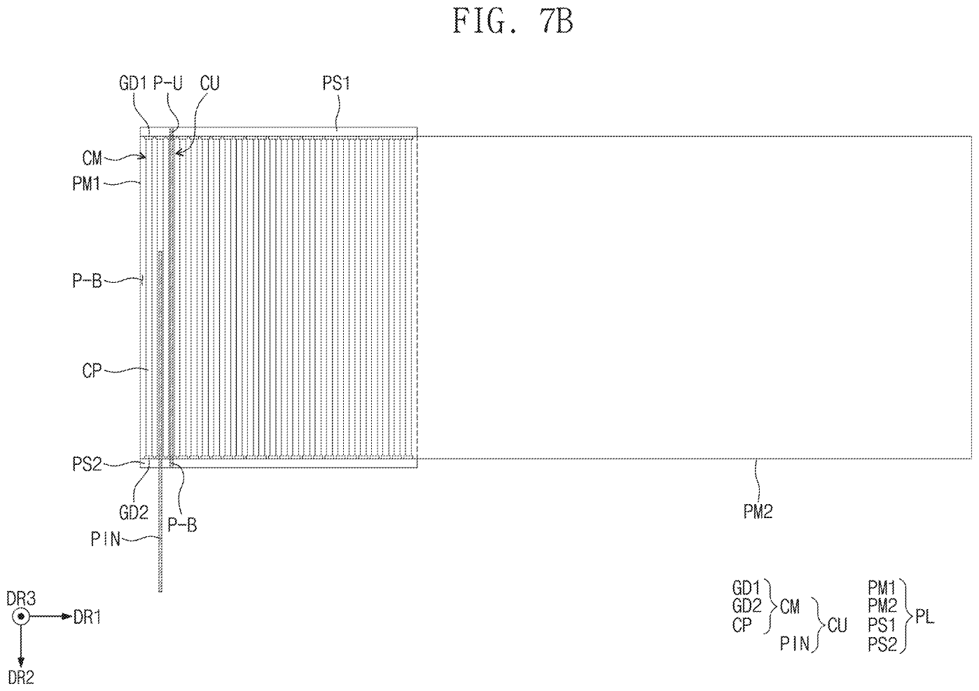

In an embodiment, the display device DD may include the display module DM, first and second cases CS1 and CS2, the roller RL, a plate PL, an adhesive layer AL, chain units CU (see FIG. 7A) including pins PIN, a flexible circuit board FPC, a driving chip D-IC, and a spacer C-SP.

In an embodiment, the display module DM may be flexible. The display module DM may include a first region AA1, a second region AA2, and a third region AA3. The first region AA1 and the third region AA3 of the display module DM may be accommodated in the case CS (see FIG. 1A) in a state of each being partially bent.

According to an embodiment, the first region AA1 may be defined as a region, of the display module DM, of which a shape is changed to correspond to a curved surface of the roller RL, when an operation state is changed according to the first mode and the second mode. The second region AA2 may be defined as a region, of the display module DM, of which a shape is maintained flat in the first mode and the second mode. Accordingly, when a mode is changed, a section in which the area of the display surface of the display device DD increases or decreases may correspond to the first region AA1 of the display module DM.

However, the invention is not limited thereto, and in an embodiment, in a rollable display device, the total region of the first region AA1 and the second region AA2 may change in shape to correspond to the curved surface of the roller RL, and be accommodated in a housing while being wound around the roller RL, but the shape change is not limited to any one embodiment.

In an embodiment, the third region AA3 may be a region bent with respect to an imaginary axis extending in the second direction DR2. The third region AA3 may be bent to face a rear surface of the plate PL.

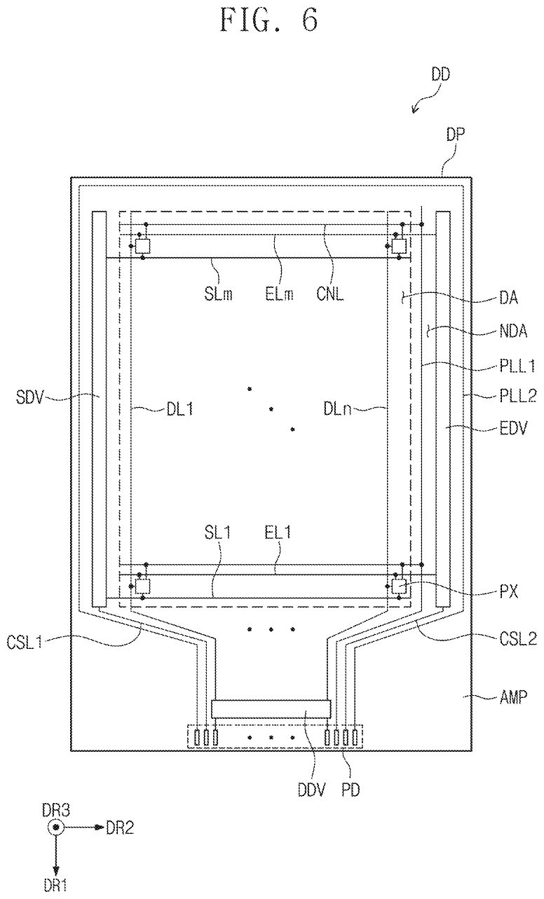

In an embodiment, a flexible circuit board FPC may be connected to the third region AA3 of the display module DM. Pads included in the flexible circuit board FPC may be connected to pads (see FIG. 6) included in the display panel DP (see FIG. 6) via an anisotropic conductive film (ACF). The display module DM may be coupled to the plate PL through the adhesive layer AL. The adhesive layer AL may include a pressure sensitive adhesive (PSA) or an optically clear adhesive (OCA), but the type of adhesive is not limited thereto.

In an embodiment, the driving chip D-IC may be connected to the flexible circuit board FPC. The driving chip D-IC may include elements for driving the display panel DP (see FIG. 6). The driving chip D-IC may be coupled to the display module DM through an adhesive layer AD, but the invention is not limited thereto. The driving chip D-IC may be mounted in the third region AA3 of the display module DM, and in this case the flexible circuit board FPC may be omitted.

In an embodiment, the display device DD may further include the spacer C-SP for shape retention while in a bent state of the third region AA3. The spacer C-SP may be disposed between an end of the third region AA3 and the rear surface of the plate PL, and may support the display module DM to maintain the bent state of the third region AA3. The spacer C-SP may be omitted in the display device DD according to an embodiment, and is not limited to any one embodiment.

In an embodiment, the plate PL may be disposed under the display module DM. When an operation state of the display device DD is changed by the roller RL, the plate PL may support the display module DM to prevent the shape of the display module DM from being changed.

In an embodiment, since the plate PL is not in contact with the roller RL, and only structures disposed under the plate PL are in contact with the roller RL, a force applied during rotation of the roller RL may not be transferred to the plate PL or the display module DM, and may be transferred only to structures disposed under the plate PL. Detailed description therefore will be made later.

In an embodiment, the display device DD may include the chain units CU (see FIG. 7A) including the pins PIN. The chain units CU (see FIG. 7A) may each include a coupling portion CM (see FIG. 7A) and the pins PIN, and the coupling portion CM (see FIG. 7A) may be coupled to the plate PL by the pin PIN. The chain units CU (see FIG. 7A) may rotate to correspond to the rotation of the roller RL in a state in which the chain units CU are each coupled to the plate PL. Detailed description therefore will be made later.

In an embodiment, the roller RL may be disposed between bent portions of the plate PL. Since the roller RL rotates, shapes of the plate PL and the display module DM may be changed. The roller RL may be accommodated in the second case CS2. The roller RL may rotate about an imaginary rotational axis RX extending along the second direction DR2. The roller RL may be coupled to at least one of the first case CS1 or the second case CS2 and may thus rotate about the rotational axis RX according to a sliding operation by which the first case CS1 gets farther away from or closer to the second case CS2.

In an embodiment, the roller RL may include a rotational portion RU having a cylindrical shape, and bumps PT protruding from the rotational portion RU, and respectively inserted between the adjacent chain units CU (see FIG. 7A). Since the bumps PT are inserted between the adjacent chain units CU during rotation of the roller RL, the roller RL may be stably coupled to the plate PL. Detailed description therefore will be made later.

In an embodiment, the display device DD may move from the first mode illustrated in FIG. 2A to the second mode illustrated in FIG. 2B in which the first case CS1 and the second case CS2 move away from each other along the first direction DR1. According to an embodiment, since a portion of the display module DM disposed under the roller RL slides due to the roller RL and is disposed over the roller RL when the display device DD changes an operation state from the first mode to the second mode, an area of the display module DM viewed by a user may increase.

In an embodiment, when the display device DD changes an operation state from the first mode to the second mode, an end of the second region AA2 spaced apart from the first region AA1 may be fixed to the first case CS1 and move along with the first case CS1. In this case, an end of the first region AA1 spaced apart from the second region AA2 may move in a direction opposite to the end of the second region AA2 coupled to the first case CS1.

According to an embodiment, a portion of the display surface corresponding to the first region AA1 in the first mode may be exposed to the outside, and when an operation mode is changed from the first mode to the second mode, an area of the first region AA1 exposed to the outside by the display opening C-OP may be increased. However, the invention is not limited thereto, and the display surface corresponding to the first region AA1 in the first mode may not be exposed to the outside.

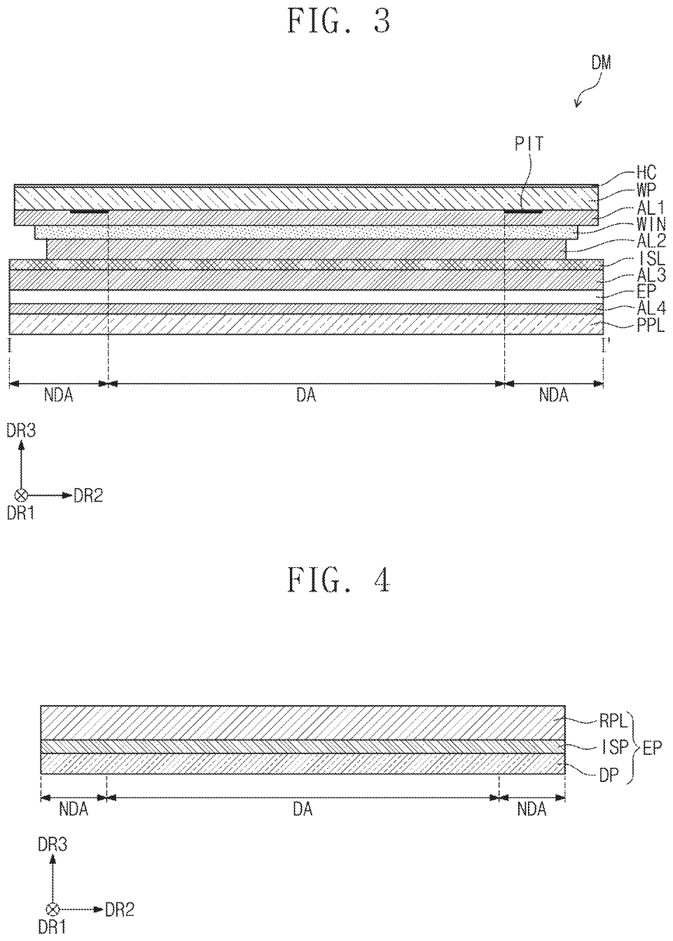

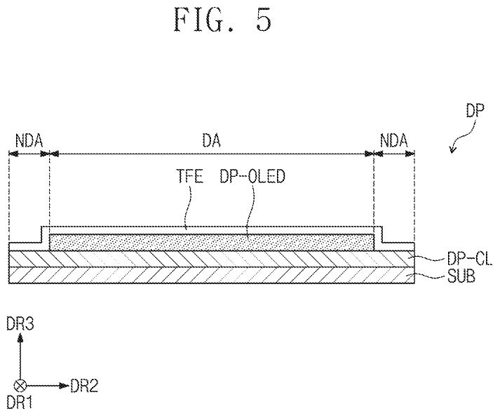

FIG. 3 is a cross-sectional view of a display module, according to an embodiment. FIG. 4 is a cross-sectional view of an electronic panel, according to an embodiment. FIG. 5 is a cross-sectional view of a display panel, according to an embodiment. FIG. 6 is a plan view of the display panel, according to an embodiment.

In an embodiment and referring to FIG. 3, a display module DM may include an electronic panel EP, an impact-absorbing layer ISL, a panel protection layer PPL, a window WIN, a window protection layer WP, a hard coating layer HC, and first to fourth adhesive layers AL1 to AL4, respectively.

In an embodiment, the electronic panel EP may display an image. The electronic panel EP may include a display panel, an input-sensing portion, and an anti-reflective layer, and a configuration of such an electronic panel EP will be described later with reference to FIG. 4.

In an embodiment, the impact-absorbing layer ISL may be disposed on the electronic panel EP. The impact-absorbing layer ISL may absorb an external impact applied from the window WIN toward the electronic panel EP to protect the electronic panel EP. The impact-absorbing layer ISL may be manufactured in a form of a stretched film.

In an embodiment, the impact-absorbing layer ISL may include a flexible plastic material. The flexible plastic material may be defined as a synthetic resin film. For example, the impact-absorbing layer ISL may include a flexible plastic material such as polyimide or polyethylene terephthalate.

In an embodiment, the window WIN may be disposed on the impact-absorbing layer ISL. The window WIN may protect the electronic panel EP from an external scratch. The window WIN may be optically transparent. The window WIN may include glass. However, the invention is not limited thereto, and the window WIN may include a synthetic resin film.

In an embodiment, the window WIN may have a single-layered or multi-layered structure. For example, the window WIN may include a plurality of synthetic resin films bonded with an adhesive, or a glass substrate and a synthetic resin film bonded with an adhesive.

In an embodiment, the window protection layer WP may be disposed on the window WIN. The window protection layer WP may include a flexible plastic material such as polyimide or polyethylene terephthalate. The hard coating layer HC may be disposed on an upper surface of the window protection layer WP. The hard coating layer HC may include any one among an organic compound, an inorganic compound, and an organic-inorganic complex compound. For example, the hard coating layer HC may include an acrylic compound, an epoxy-based compound, or a combination thereof. In another embodiment, the hard coating layer HC may include any one inorganic compound among silicon nitride, silicon oxynitride, silicon oxide, zirconium oxide, aluminum oxide, tantalum oxide, niobium oxide, glass bead.

In an embodiment, the printing layer PIT may be disposed on a lower surface of the window protection layer WP. The printing layer PIT may have a black color, but a color of the printing layer PIT is not limited thereto. The printing layer PIT may be disposed adjacent to a border of the window protection layer WP. The printing layer PIT may overlap a non-display region NDA.

In an embodiment, the panel protection layer PPL may be disposed under the electronic panel EP. The panel protection layer PPL may protect a lower portion of the electronic panel EP. The panel protection layer PPL may include a flexile plastic material. For example, the panel protection layer PPL may include polyimide or polyethylene terephthalate.

In an embodiment, a first adhesive layer ALI may be disposed between the window protection layer WP and the window WIN. The window protection layer WP and the window WIN may be bonded to each other by the first adhesive layer AL1. The first adhesive layer AL1 may cover the printing layer PIT.

In an embodiment, a second adhesive layer AL2 may be disposed between the window WIN and the impact-absorbing layer ISL. The window WIN and the impact-absorbing layer ISL may be bonded to each other by the second adhesive layer AL2.

In an embodiment, a third adhesive layer AL3 may be disposed between the impact-absorbing layer ISL and the electronic panel EP. The impact-absorbing layer ISL and the electronic panel EP may be bonded to each other by the third adhesive layer AL3.

In an embodiment, a fourth adhesive layer AL4 may be disposed between the electronic panel EP and the panel protection layer PPL. The electronic panel EP and the panel protection layer PPL may be bonded to each other by the fourth adhesive layer AL4.

In an embodiment, the first to fourth adhesive layers AL1 to AL4, respectively, may each include a pressure sensitive adhesive (PSA) or an optically clear adhesive (OCA), but a type of the adhesive is not limited thereto.

In an embodiment and referring to FIG. 4, the electronic panel EP may include the display panel DP, the input-sensing portion ISP disposed on the display panel DP, and the anti-reflective layer RPL disposed on the input-sensing portion ISP. FIG. 4 exemplarily illustrates a cross-section of the electronic panel EP viewed in the first direction DR1.

In an embodiment, the display panel DP may be flexible. For example, the display panel DP may include a flexible substrate and a plurality of elements disposed on the flexible substrate.

In an embodiment, the display panel DP may be an emission-type display panel, but is not specially limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, or the like. Hereinafter, the display panel DP will be described as an organic light-emitting display panel.

In an embodiment, the input-sensing portion ISP may include a plurality of sensing portions (not shown) for sensing an external input. For example, the input-sensing portion ISP may sense the external input in a capacitive way, but sensing of the input-sensing portion ISP is not limited thereto. When the electronic panel EP is manufactured, the input-sensing portion ISP may be formed directly on the electronic panel EP.

In an embodiment, the anti-reflective layer RPL may be disposed on the input-sensing portion ISP. When the electronic panel EP is manufactured, the anti-reflective layer RPL may be formed directly on the input-sensing portion ISP. The anti-reflective layer RPL may be defined as an anti-reflective film for external light. The anti-reflective layer RPL may reduce reflectance for external light entering the display panel DP from above the display device DD.

In an embodiment, when the external light propagated toward the display panel DP reflects on the display panel DP and is supplied to an external user again, the user may view the external light, like a mirror. To prevent such a phenomenon, the anti-reflective layer RPL may include, for example, a plurality of color filters that display the same color as pixels of the display panel DP.

In an embodiment, the color filters may perform filtering such that the external light becomes light having the same color as the pixels. In this case, the external light may be invisible to the user. However, the invention is not limited thereto, and the anti-reflective layer RPL may include a retarder and/or a polarizer to reduce the external light reflectance.

For example, in an embodiment, the input-sensing portion ISP may be formed directly on the display panel DP, and the anti-reflective layer RPL may be formed directly on the input-sensing portion ISP, but the invention is not limited thereto. For example, in another embodiment, the input-sensing portion ISP may be separately manufactured and attached to the display panel DP by an adhesive layer, and the anti-reflective layer RPL may be separately prepared and attached to the input-sensing portion ISP by an adhesive layer.

FIG. 5 is a cross-sectional view of a display panel showing a configuration of the display panel illustrated in FIG. 4, according to an embodiment.

FIG. 5 exemplarily illustrates a cross-section of a display panel DP viewed in the first direction DR1, according to an embodiment.

In an embodiment and referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

In an embodiment, the substrate SUB may include a display region DA and a non-display region NDA around the display region DA. The substrate SUB may include a flexible plastic material such as polyimide. The display element layer DP-OLED may be disposed on the display region DA.

In an embodiment, the display panel DP may include a plurality of insulating layers, a semiconductor pattern, a conductive pattern, a signal line, etc. An insulating layer, a semiconductor layer, and a conductive layer are formed through coating, deposition, or the like. Thereafter, the insulating layer, the semiconductor layer, and the conductive layer may be selectively patterned through photolithography and etching. The semiconductor pattern, the conductive pattern, the signal line, etc., included in the circuit element layer DP-CL and the display element layer DP-OLED are formed in such a way.

In an embodiment, the circuit element layer DP-CL includes at least one insulating layer and a circuit element. The insulating layer includes at least one inorganic layer and at least one organic layer. The circuit element includes signal lines, a driving circuit of a pixel, etc.

In an embodiment, the display element layer DP-OLED includes a conductive partition wall and a light-emitting element. The light-emitting element may include an anode, a light-emitting pattern, and a cathode, and the light-emitting pattern may include at least a light-emitting layer.

In an embodiment, the thin-film encapsulation layer TFE includes a plurality of thin-films. Some of the thin-films are disposed to improve an optical efficiency, and others are disposed to protect organic light-emitting diodes.

In an embodiment, a plurality of pixels may be disposed in the display region DA. The pixels may be connected to transistors disposed in the circuit element layer DP-CL and may include light-emitting elements disposed in the display element layer DP-OLED.

In an embodiment, the thin-film encapsulation layer TFE may be disposed on the circuit element layer DP-CL to cover the display element layer DP-OLED. The thin-film encapsulation layer TFE may include inorganic layers and an organic layer between the inorganic layers. The inorganic layers may protect the pixels from moisture/oxygen. The organic layer may protect the pixels from foreign matters such as duct particles.

FIG. 6 is a plan view of the display panel illustrated in FIG. 5, according to an embodiment.

In an embodiment and referring to FIG. 6, a display device DD may include a display panel DP, a scan driver SDV, a data driver DDV, a light emission driver EDV, and a plurality of pads PD.

In an embodiment, the display panel DP may have a rectangular shape having long sides extending in the first direction DR1 and short sides extending in the second direction DR2, but a shape of the display panel DP is not limited thereto. The display panel DP may include a display region DA and a non-display region NDA surrounding the display region DA.

In an embodiment, the display panel DP may include a plurality of pixels PX, a plurality of scanning lines SL1 to SLm, a plurality of data lines DL1 to DLn, a plurality of light-emitting lines EL1 to ELm, first and second control lines CSL1 and CSL2, respectively, first and second power lines PLL1 and PLL2, respectively, and connection lines CNL. m and n are natural numbers.

In an embodiment, the pixels PX may be disposed in the display region DA. The scan driver SDV and the light emission driver EDV may be disposed in the non-display region NDA to be respectively disposed adjacent to the long sides of the display panel DP. The data driver DDV may be disposed in the non-display region NDA to be adjacent to any one short side of the short sides of the display panel DP. When viewed on a plane, the data driver DDV may be disposed adjacent to a lower end of the display panel DP.

In an embodiment and referring to FIG. 6, an accommodation portion AMP may be defined as the non-display region NDA disposed adjacent to the lower end of the display panel DP. The data driver DDV may be disposed in the accommodation portion AMP.

In an embodiment, the scanning lines SL1 to SLm may extend in the second direction DR2 to be connected to the pixels PX and the scan driver SDV. The data lines DL1 to DLn may extend in the first direction DR1 to be connected to the pixels PX and the data driver DDV. The light-emitting lines EL1 to ELm may extend in the second direction DR2 to be connected to the pixels PX and the light emission driver EDV.

In an embodiment, a first power line PLL1 may extend in the first direction DR1 to be disposed in the non-display region NDA. The first power line PLL1 may be disposed between the display region DA and the light emission driver EDV.

In an embodiment, the connection lines CNL may extend in the second direction DR2 and be arranged in the first direction DR1 to be connected to the first power line PLL1 and the pixels PX. A first voltage may be applied to the pixels PX through the first power line PLL1 and the connection lines CNL connected to each other.

In an embodiment, a second power line PLL2 may be disposed in the non-display region NDA and may extend along the long sides of the display panel DP and the other short side of the display panel DP where the data driver DDV is not disposed. The second power line PLL2 may be disposed more outside than the scan driver SDV and the light emission driver EDV.

Although not shown, in an embodiment, the second power line PLL2 may extend toward the display region DA to be connected to the pixels PX. A second voltage having a lower level than the first voltage may be applied to the pixels PX through the second power line PLL2.

In an embodiment, a first control line CSL1 may be connected to the scan driver SDV and extend toward the lower end of the display panel DP. A second control line CSL2 may be connected to the light emission driver EDV and extend toward the lower end of the display panel DP. The data driver DDV may be disposed between the first control line CSL1 and the second control line CSL2.

In an embodiment, the pads PD may be disposed in the non-display region NDA to be disposed adjacent to the lower end of the display panel DP, and be more adjacent to the lower end of the display panel DP than the data driver DDV. The data driver DDV, the first power line PLL1, the second power line PLL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Although not shown, in an embodiment, the display device DD may further include a timing controller for controlling the operations of the scan driver SDV, the data driver DDV, and the light emission driver EDV, and a voltage generation unit for generating the first and second voltages. The timing controller and the voltage generation unit may be connected to the pads PD through a flexible circuit board FPC (see FIG. 2A).

In an embodiment, the scan driver SDV may generate a plurality of scanning signals, and the scanning signals may be applied to the pixels PX through the scanning lines SL1 to SLm. The data driver DDV may generate a plurality of data voltages, and the data voltages may be applied to the pixels PX through the data lines DL1 to DLn. The light emission driver EDV may generate a plurality of light-emitting signals, and the light-emitting signals may be applied to the pixels PX through the light-emitting lines EL1 to ELm.

In an embodiment, the pixels PX may receive the data voltages in response to the scanning signals. The pixels PX may display an image by emitting light having luminance corresponding to the data voltages in response to the light-emitting signals.

FIG. 7A is an exploded perspective view of a display device, according to an embodiment. FIG. 7B is a plan view illustrating a coupling relationship of a plate and chain units, according to an embodiment. FIGS. 7A and 7B are diagrams for describing a connection relationship of a plate PL and chain units CU included in the display device DD illustrated in FIG. 2A.

In an embodiment and referring to FIG. 7A, an adhesive layer AL may be disposed between a display module DM and the plate PL. The display module DM and the plate PL may be coupled via the adhesive layer AL. The adhesive layer AL may include any one of a pressure sensitive adhesive (PSA) or an optically clear adhesive (OCA).

In an embodiment, the plate PL may be disposed under the display module DM. The plate PL may include a first portion PM1, a second portion PM2, a first sidewall PS1, and a second sidewall PS2. The plate PL may be substantially provided as a single plate or provided as an integrated shape, and will be separately described for each region for convenience of explanation. The plate PL according to an embodiment may include stainless steel.

In an embodiment, the first portion PM1 may overlap a first region AA1 of the display module DM. Accordingly, when a shape of the first region AA1 of the display module DM is changed to correspond to a curved surface of a roller RL, the shape of the first portion PM1 may be changed to correspond to the curved surface of the roller RL along with the first region AA1.

In an embodiment, the second portion PM2 may overlap the second region AA2. The second portion PM2 may be defined as a region which maintains a flat state along with the second region AA2 in the first mode and the second mode. In the present disclosure, the first portion PM1 and the second portion PM2 of the plate PL may be defined as ‘a base portion’.

In an embodiment, the plate PL may include the first sidewall PSI and the second sidewall PS2 which are spaced apart from each other along the second direction DR2 with the first portion PM1 therebetween. The first sidewall PS1 and the second sidewall PS2 may protrude downward from the base portion.

In an embodiment, when the shape of the first portion PMI is changed to correspond to the curved surface of the roller RL, shapes of the first sidewall PSI and the second sidewall PS2 may be changed to correspond to the curved surface of the roller RL along with the first portion PM1.

According to an embodiment, thicknesses of the first sidewall PS1 and the second sidewall PS2 in the third direction DR3 may be greater than a thickness of the first portion PM1. A display module DM-facing surface of the first sidewall PS1 and the second sidewall PS2 may define the same plane as a display module DM-facing surface of the first portion PM1, and in a state in which the display module is bent around the roller RL, a lower surface of each of the first sidewall PS1 and the second sidewall PS2 may further protrude downward toward the center of the roller RL (see FIG. 2A) than a lower surface of the first portion PM1 (see FIG. 2A).

According to an embodiment, pin holes P-H, which at least partially penetrate the first sidewall PS1 and the second sidewall PS2 in a direction from an inner side surface toward an outer side surface, may be defined in each of the first sidewall PS1 and the second sidewall PS2, the inner side surface and outer side surface facing each other in the second direction DR2. The pin holes P-H may be formed in portions of the first sidewall PS1 and the second sidewall PS2, protruding downward from the first portion PM1.

In an embodiment, the chain units CU may be disposed between the first sidewall PS1 and the second sidewall PS2, and be disposed under the plate PL overlapping the first portion PM1. The chain units CU may be arranged along the first direction DR1, and be each arranged along the second direction DR2.

In an embodiment, the chain units CU may each include a pin PIN and a coupling portion CM. A chain groove, into which the pin PIN may be inserted, may be defined inside the coupling portion CM. A shape of the chain groove may correspond to a shape of the pin PIN on a cross-section taken along the first direction DR1.

In an embodiment, the coupling portion CM may include a first guide portion GD1, a second guide portion GD2, and a central portion CP. The first guide portion GD1 may be disposed adjacent to one end of the pin PIN, coupled to the pin hole P-H defined in the first sidewall PS1, and the second guide portion GD2 may be disposed adjacent to the other end of the pin PIN, coupled to the pin holes P-H defined in the second sidewall PS2. The central portion CP may be disposed between the first guide portion GD1 and the second guide portion GD2.

In an embodiment, t width of the central portion CP in the second direction DR2 may be greater than widths of the first guide portion GD1 and the second guide portion GD2 in the second direction DR2. On a cross-section taken along the first direction DR1, a width of the central portion CP may be smaller than widths of the first guide portion GD1 and the second guide portion GD2 in the second direction DR2.

According to an embodiment, when the roller RL (see FIG. 2A) is being rolled, the first guide portion GD1 and the second guide portion GD2 may be in contact with a rear surface of the plate PL overlapping the first portion PM1, but the central portion CP may be in non-contact with the rear surface of the plate PL overlapping the first portion PM1.

According to an embodiment, the first guide portion GD1, the second guide portion GD2, and the central portion CP may each have a cylindrical shape. In addition, the pin PIN may also have a cylindrical shape.

In an embodiment, bumps PT (see FIG. 2A) included in the roller RL (see FIG. 2A) may be disposed between the central portions CP to be disposed adjacent to each other along a circumference of the roller RL (see FIG. 2A). The bumps PT (see FIG. 2A) may be stably coupled to the central portions CP by the first guide portion GD1 and the second guide portion GD2.

In an embodiment and referring to FIG. 7B, one end of the pin PIN may be coupled to the pin hole P-H defined in the first sidewall PS1, and the other end opposed to the one end of the pin PIN in the second direction DR2 may be coupled to the pin hole P-H defined in the second sidewall PS2. FIG. 7B illustrates that the pin PIN passes through the coupling portion CM from the outside of the second sidewall PS2 and is inserted into the pin hole P-H of the first sidewall PS1, but the invention is not limited thereto. In an embodiment, the pin PIN and the coupling portion CM may be provided as an integrated shape, and are not limited to any one embodiment.

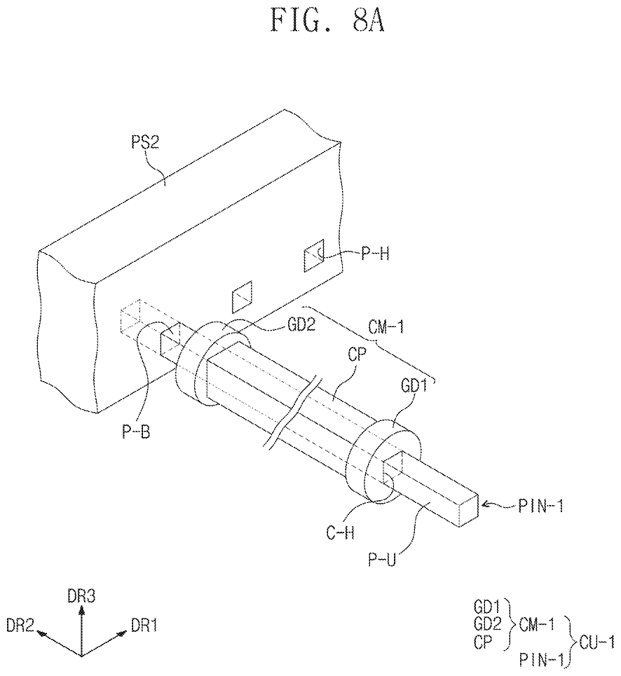

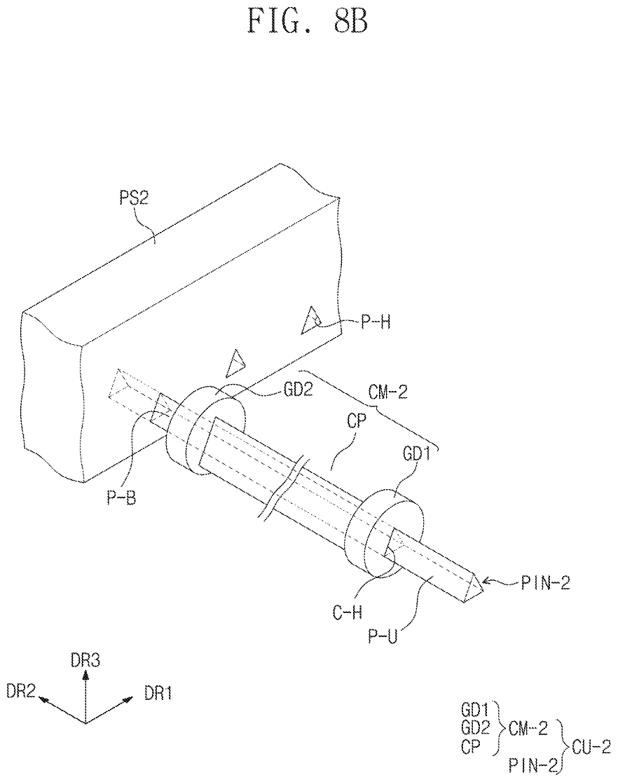

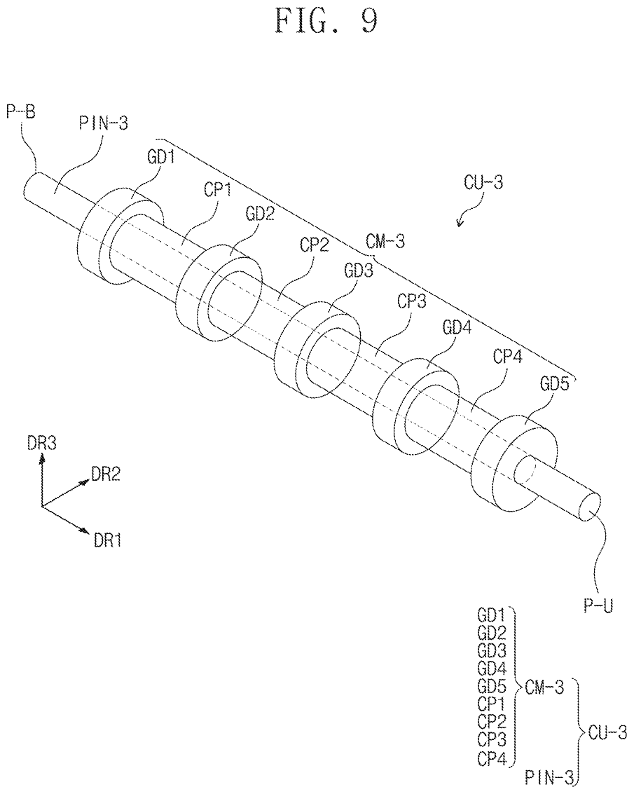

FIG. 8A is a perspective view illustrating a configuration of a display device, according to an embodiment. FIG. 8B is a perspective view of a configuration of the display device, according to an embodiment. FIG. 9 is a perspective view illustrating a chain unit, according to an embodiment. An embodiment pertaining to chain units to be described with reference to FIGS. 8A to 9 may be applied to the display device DD (see FIG. 1A) which has been described with reference to FIGS. 1 to 7B.

Referring to FIG. 8A, a chain unit CU-1, according to an embodiment, may include a pin PIN-1 and a coupling portion CM-1.

In an embodiment, the coupling portion CM-1 may include a first guide portion GD1, a second guide portion GD2, and a central portion CP. The first guide portion GD1 may be disposed adjacent to one end P-U of the pin PIN-1 and coupled to the pin hole P-H (see FIG. 7A) defined in the first sidewall PS1 (see FIG. 7A), and the second guide portion GD2 may be disposed adjacent to the other end P-B of the pin PIN-1 and coupled to the pin hole P-H defined in the second sidewall PS2. The central portion CP may be disposed between the first guide portion GD1 and the second guide portion GD2.

In an embodiment, a width of the central portion CP in the second direction DR2 may be greater than widths of the first guide portion GD1 and the second guide portion GD2 in the second direction DR2. On a cross-section taken along the first direction DR1, a width of the central portion CP may be smaller than widths of the first guide portion GD1 and the second guide portion GD2 in the second direction DR2.

According to an embodiment, the pin PIN-1 may have a square pillar shape. Accordingly, the pin hole P-H defined in the second sidewall PS2 may have a shape corresponding to the shape of the pin PIN-1. In addition, a shape of the chain groove C-H defined in the coupling portion CM-1 may also have a shape corresponding to the shape of the pin PIN-1, but the invention is not limited thereto. The coupling portion CM-1 may have a cylindrical shape, and the shape of the chain groove C-H defined inside the coupling portion CM-1 may also have a shape corresponding to the shape of the pin PIN-1.

Referring to FIG. 8B, a chain unit CU-2, according to an embodiment, may include a pin PIN-2 and a coupling portion CM-2.

In an embodiment, the coupling portion CM-2 may include the first guide portion GD1, the second guide portion GD2, and the central portion CP. The first guide portion GD1 may be disposed adjacent to one end P-U of the pin PIN-2 and coupled to the pin hole P-H (see FIG. 7A) defined in the first sidewall PS1 (see FIG. 7A), and the second guide portion GD2 may be disposed adjacent to the other end P-B of the pin PIN-2 and coupled to the pin hole P-H defined in the second sidewall PS2. The central portion CP may be disposed between the first guide portion GD1 and the second guide portion GD2.

According to an embodiment, the pin PIN-1 may have a triangular pillar shape. Accordingly, the pin hole P-H defined in the second sidewall PS2 may have a shape corresponding to the shape of the pin PIN-2. In addition, the shape of the chain groove C-H defined in the coupling portion CM-2 may also have a shape corresponding to the shape of the pin PIN-2, but the invention is not limited thereto. The coupling portion CM-2 may have a cylindrical shape, and the shape of the chain groove C-H defined therein may have a shape corresponding to the shape of the pin PIN-2.

In an embodiment, according to the pins PIN-1 and PIN-2 described in FIGS. 8A and 8B, the pins PIN-1 and PIN-2 have a polygonal shape on a cross-section, and may thus be stably coupled to the sidewalls PS1 and PS2 (see FIG. 7A).

In an embodiment and referring to FIG. 9, a chain unit CU-3 may include first to fifth guide portions GD1, GD2, GD3, GD4 and GD5, respectively, and first to fourth central portions CP1, CP2, CP3, and CP4, respectively, arranged in the first direction DR1. The first to fifth guide portions GD1, GD2, GD3, GD4 and GD5, respectfully, may be arranged to be spaced apart from each other along the first direction DR1, and the first to fourth central portions CP1, CP2, CP3, and CP4, respectively, may be disposed between the first to fifth guide portions GD1, GD2, GD3, GD4 and GD5, respectively, to be spaced apart from each other along the first direction DR1. Guide portions and central portions are described as separate components in FIG. 9 for convenience of description, but the guide portions and the central portions may be provided as an integrated shape.

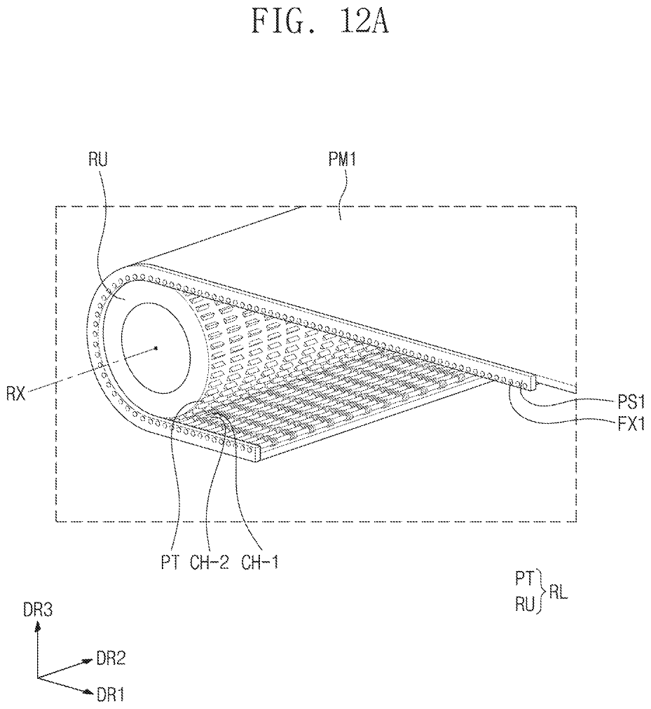

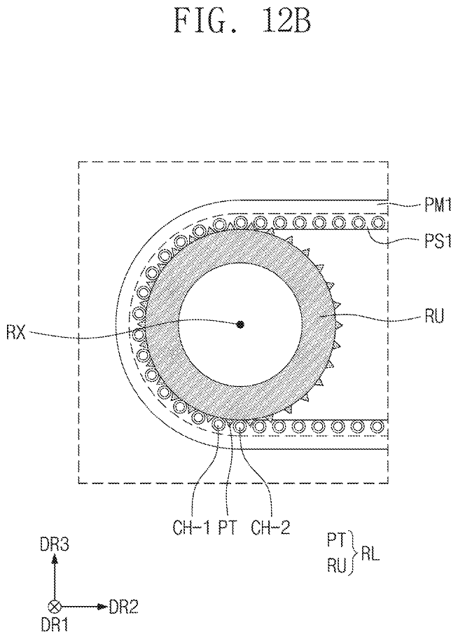

In an embodiment, bumps inserted into the chain unit CU-3 may have the same shape as bumps PT (see FIG. 12A) included in a roller RL illustrated in FIG. 12A. Accordingly, each of the bumps may be included in the chain units CU-3 different from each other, and may be inserted between the central portions adjacent to each other along a circumference of the roller RL (see FIG. 12A).

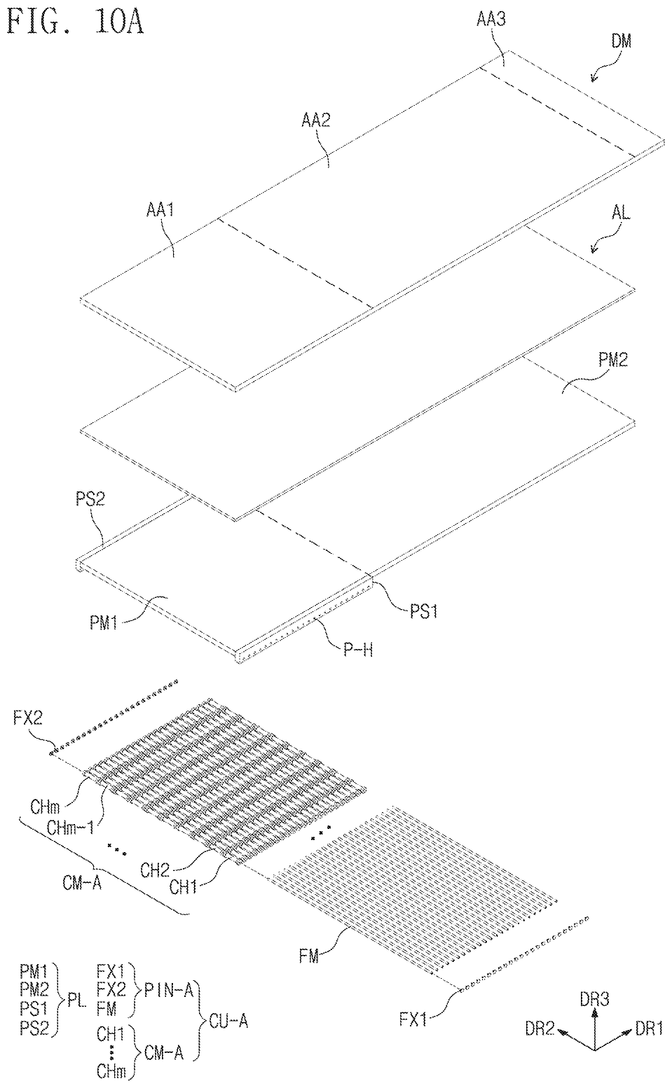

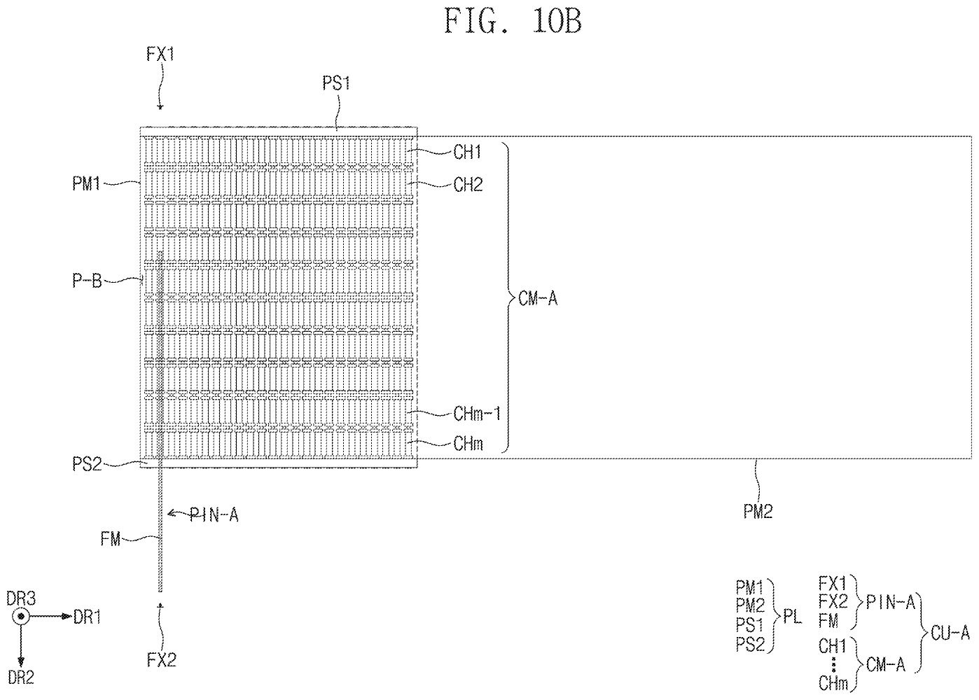

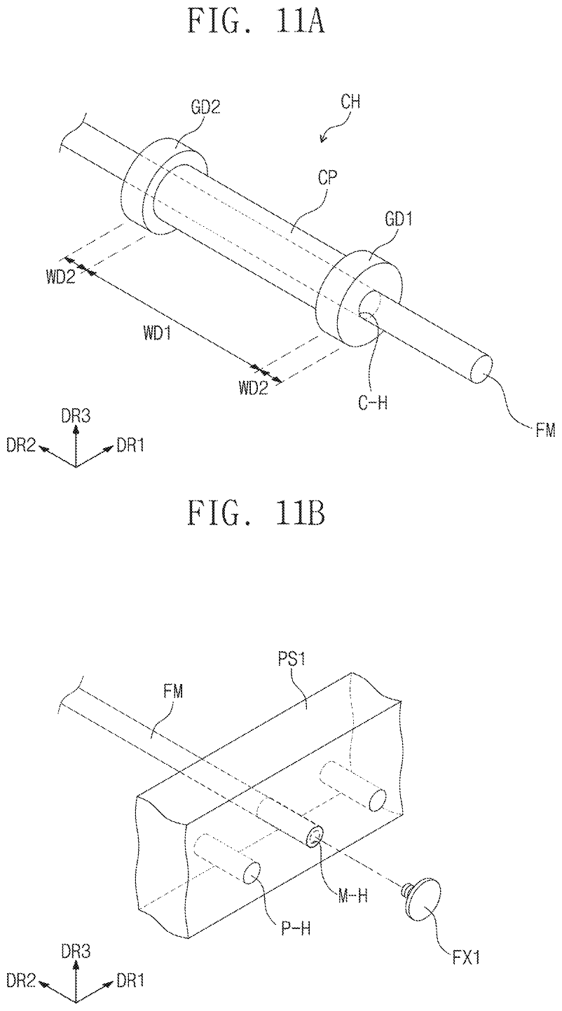

FIG. 10A is an exploded perspective view of a display device, according to an embodiment. FIG. 10B is a plan view illustrating a coupling relationship of a plate and chain units, according to an embodiment. FIG. 11A is a perspective view of a chain unit, according to an embodiment. FIG. 11B is an exploded perspective view of a pin, according to an embodiment.

In an embodiment and referring to FIGS. 10A and 10B, an adhesive layer AL may be disposed between a display module DM and a plate PL. The display module DM and the plate PL may be coupled to each other by the adhesive layer AL.

In an embodiment, the plate PL may be disposed under the display module DM. The plate PL may include a first portion PM1, a second portion PM2, a first sidewall PS1, and a second sidewall PS2. The plate PL, according to an embodiment, may include stainless steel.

In an embodiment, the first portion PM1 may overlap a first region AA1 of the display module DM. Accordingly, when a shape of the first region AA1 of the display module DM is changed to correspond to a curved surface of a roller RL (see FIG. 2A), a shape of the first portion PM1 may be changed to correspond to the curved surface of the roller RL along with the first region AA1.

In an embodiment, the second portion PM2 may overlap a second region AA2. The second portion PM2 may be defined as a region which maintains a flat state with the second region AA2 in the first mode and the second mode. In the present disclosure, the first portion PM1 and the second portion PM2 of the plate PL may be defined as ‘a base portion’.

In an embodiment, the plate PL may include the first sidewall PS1 and the second sidewall PS2 spaced apart from each other along the second direction DR2 with the first portion PM1 therebetween. The first sidewall PS1 and the second sidewall PS2 may protrude downward from the base portion.

According to an embodiment, pin holes P-H which at least partially penetrate the first sidewall PS1 and the second sidewall PS2 in a direction from an inner side surface toward an outer side surface may be defined in each of the first sidewall PSI and the second sidewall PS2, where the inner side surface and the outer side surface are facing each other in the second direction DR2. The pin holes P-H may be formed in portions of the first sidewall PS1 and the second sidewall PS2 and may be protruding downward from the first portion PM1.

In an embodiment, chain units CU-A may be disposed between the first sidewall PS1 and the second sidewall PS2, and be disposed under the plate PL overlapping the first portion PM1. The chain units CU-A may be arranged along the first direction DR1 and each may extend along the second direction DR2.

In an embodiment, the chain units CU-A may each include a pin PIN-A and a coupling unit CM-A. A chain groove, into which the pin PIN-A may be inserted, may be defined inside the coupling unit CM-A. A shape of the chain groove may correspond to a shape on a cross-section taken along the first direction DR1.

In an embodiment, the coupling unit CM-A may include coupling portions CHI, CH2, CHm-1, and CHm arranged to be spaced apart from each other along the second direction DR2. The coupling portions CH1, CH2, CHm-1, and CHm may be arranged to be spaced apart from each other along the second direction DR2 and be coupled to the first sidewall PS1 and the second sidewall PS2 by one pin PIN-A.

In an embodiment, the pin PIN-A may include an insertion portion FM, a first fixing portion FX1, and a second fixing portion FX2. The insertion portion FM may be inserted into the chain groove defined in the coupling unit CM-A.

In an embodiment, FIG. 11A exemplarily illustrates a coupling relationship of one coupling portion CH among the coupling portions CH1, CH2, CHm-1, and CHm and a pin PIN. A coupling portion CH to be described with reference to FIG. 11A may correspond to any one among the coupling portions CH1, CH2, CHm-1, and CHm described with reference to FIG. 10A.

In an embodiment and referring to FIG. 11A, the coupling portion CH may include a first guide portion GD1, a second guide portion GD2, and a central portion CP. According to an embodiment, the first guide portion GD1 and the second guide portion GD2, which are included in the coupling portions to be located different from each other and face each other in the second direction DR2, may be spaced apart from each other, and thus the pin PIN-A may be exposed.

In an embodiment, a first width WD1 of the central portion CP in the second direction DR2 may be greater than second width WD2 of each of the first guide portion GD1 and the second guide portion GD2 in the second direction DR2. On a cross-section taken along the first direction DR1, a width of the central portion CP may be smaller than widths of the first guide portion GD1 and the second guide portion GD2 in the second direction DR2.

According to an embodiment, when the roller RL (see FIG. 2A) is rolled, the first guide portion GD1 and the second guide portion GD2 may be in contact with a rear surface of the plate PL overlapping the first portion PM1, but the central portion CP may be in non-contact with the rear surface of the plate PL overlapping the first portion PM1.

According to an embodiment, the first guide portion GD1, the second guide portion GD2, and the central portion CP may each have a cylindrical shape. In addition, the pin PIN-A may also have a cylindrical shape. Accordingly, the chain groove C-H defined in the coupling portion CH may be defined as a cylindrical shape.

In an embodiment, bumps inserted into the chain units CU-A may have the same shape as the bumps PT (see FIG. 12A) included in the roller RL illustrated in FIG. 12A. Accordingly, each of the bumps may be included in the chain units CU-3 (See FIG. 9) to be located different from each other, and may be inserted between the central portions adjacent to each other along a circumference of the roller RL (see FIG. 12A).

In an embodiment and referring to FIGS. 10A and 11B, the pin PIN-A may include an insertion portion FM, a first fixing portion FX1, and a second fixing portion FX2. FIG. 11B illustrates that the first fixing portion FX1 and the insertion portion FM are fixed to the first sidewall PS1, and description related thereto may also be similarly applied to the second fixing portion FX2.

In an embodiment, the first fixing portion FX1 may be inserted in a direction from the outside of the first sidewall PS1 toward the inside of the first sidewall PS1. The first fixing portion FX1 may be fixed, through a bolt-nut fastening mechanism, to the insertion portion FM inserted into the pin hole P-H of the first sidewall PS1, but the invention is not limited thereto. In an embodiment, the first fixing portion FX1 may be connected to a groove defined in the insertion portion FM through press-fitting, and is not limited to any one embodiment.

According to an embodiment, since the insertion portion FM is coupled to the first sidewall PS1 and the second sidewall PS2 by the first and second fixing portions FX1 and FX2, the coupling units CM-A may be stably fixed to the plate PL.

In an embodiment and referring to FIGS. 12A and 12B, a roller RL may include a rotational portion RU having a cylindrical shape, and bumps PT protruding from the rotational portion RU. In an embodiment, the bumps PT may be arranged apart from each other along a circumference of the rotational portion RU and along the second direction DR2, which is an extension direction. According to an embodiment, a cross-sectional shape of each of the bumps PT may be a triangle.

In an embodiment, the bumps PT may be respectively disposed between the different chain units CU-A (see FIG. 10A). For example, one bump PT, according to an embodiment, may be inserted into a space defined between a first central portion CH-1 included in one coupling portion, and a first central portion CH-1 included in another coupling portion to be located adjacent to the one coupling portion. Accordingly, a width of each of the bumps PT in the second direction DR2 may be smaller than or equal to a width of the central portion in the second direction DR2. When the roller RL is rolled with respect to a rotational axis RX, the bumps PT may not affect the plate PL (see FIG. 10A) and the display module DM.

According to an embodiment, when the roller RL rotates, a portion to which a rotational force of the roller RL is directly applied is the chain units CU-A (see FIG. 10A) and the pins PIN-A (see FIG. 10A) connected to the first and second sidewalls PS1 and PS2, and the rotational force of the roller RL is not applied to the first portion PM1 and the second portion PM2 of the plate PL facing the display module DM.

In an embodiment, since factors, by which the roller RL and the plate PL disposed under the display module DM affect a display surface of the display module DM, are removed, the display device DD having improved surface quality and appearance may be provided although the display device DD repeats a sliding operation. In addition, a typical multi-bar structure disposed under a plate is omitted, and thus the display device DD in which a structure included in a sliding portion is simplified may be supplied.

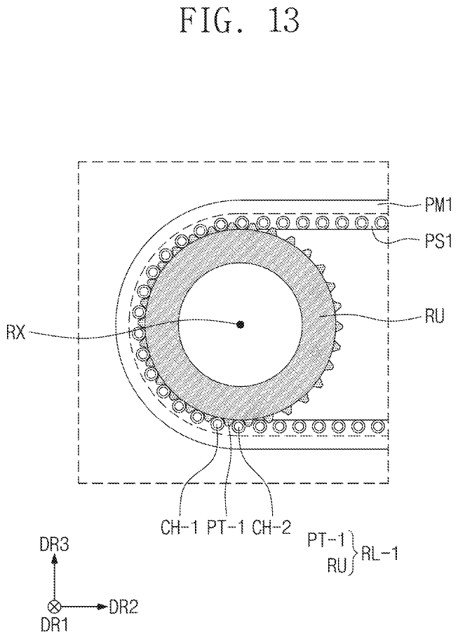

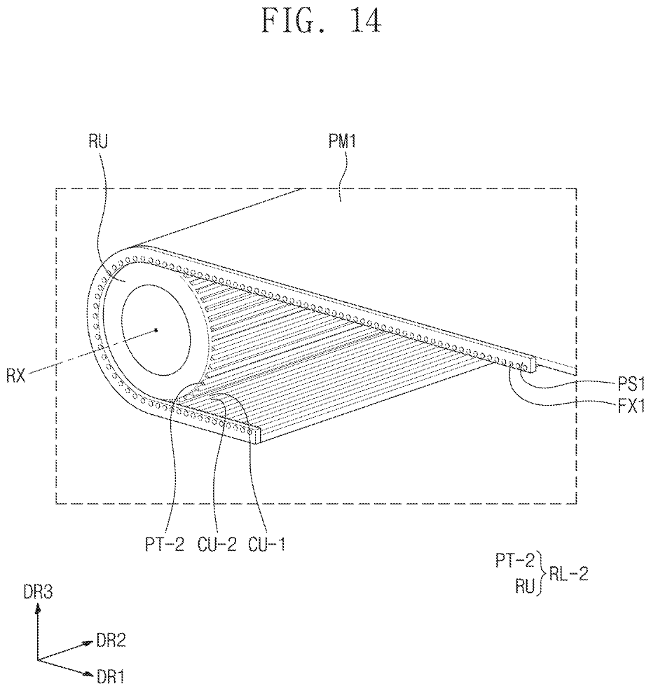

FIG. 13 is a cross-sectional view illustrating an arrangement relationship between a roller and a plate, according to an embodiment. FIG. 14 is a perspective view illustrating an arrangement relationship between the roller and the plate, according to an embodiment. FIG. 13 illustrates a region corresponding to FIG. 12B, and FIG. 14 illustrates a region corresponding to FIG. 12A.

In an embodiment and referring to FIG. 13, a roller RL-1 may include a rotational portion RU having a cylindrical shape and bumps PT-1 protruding from the rotational portion RU. The bumps PT-1 may be arranged apart from each other along a circumference of the rotational portion RU and along the second direction DR2, which is an extension direction. According to an embodiment, a cross-sectional shape of each of the bumps PT-1 may be a trapezoid, but the invention is not limited thereto. The cross-sectional shape of each of the bumps PT-1, according to an embodiment, may be any one among a quadrangle, a rectangle, and a semi-circle.

In an embodiment, the bumps PT-1 may be respectively disposed between the different chain units CU (see FIG. 7A). According to an embodiment, one bump PT-1 may be inserted into a space defined between the first central portion CH-1 included in one coupling portion CM and the second central portion CH-2 included in another coupling portion CM disposed adjacent to the one coupling portion CM.

In an embodiment and referring to FIG. 14, a roller RL-2 may include a rotational portion RU having a cylindrical shape and bumps PT-2 protruding from the rotational portion RU. The bumps PT-2 may be arranged apart from each other along a circumference of the rotational portion RU. In an embodiment, the bumps PT-2 may each extend along the second direction DR2. According to an embodiment, a cross-sectional shape of each of the bumps PT-2 may be a trapezoid.

According to an embodiment, since factors by which a roller and a plate affect a display surface of a display module are removed, a display device with improved surface quality and appearance may be supplied. In addition, the display device in which a structure included in a sliding portion is simplified may be provided.

Although embodiments of the invention have been described for illustrative purposes, those skilled in the art will appreciate that various modifications, and substitutions are possible, without departing from the scope and spirit of the invention. Accordingly, the scope of the invention is not limited to the detailed description of this specification, figures and/or the appended claims. Moreover, the embodiments or parts of the embodiments may be combined in whole or in part without departing from the scope of the invention.

What is claimed is:

1. A display device comprising:
a display module;
a plate including a base portion, and a first sidewall and a second sidewall protruding downward from the base portion to face each other, and disposed under the display module;
chain units disposed between the first sidewall and the second sidewall to be spaced apart from each other along a first direction, and each of the chain units extending along a second direction crossing the first direction to be coupled to the first sidewall and the second sidewall; and
a roller including bumps disposed between the chain units to be adjacent to each other, and overlapping the base portion,
wherein the display module overlapping the base portion, the base portion, the first sidewall, and the second sidewall are bent with respect to the roller.

2. The display device of claim 1, wherein the chain units each comprise a coupling portion which extends in the second direction and in which a chain groove is defined, and a pin inserted into the chain groove, and of which one end and the other end of the chain units are opposed to each other in the second direction and are protruding from the coupling portion.

3. The display device of claim 2, wherein the first sidewall and the second sidewall respectively comprise pin holes of which at least a portion of the first sidewall and the second sidewall is penetrated by the pin holes, and into which the one end and the other end of each of the chain units are inserted.

4. The display device of claim 3, wherein the pin further comprises a first fixing portion inserted into the pin hole of the first sidewall to fix the one end and the first sidewall, and a second fixing portion inserted into the pin hole of the second sidewall to fix the other end and the second sidewall.

5. The display device of claim 3, wherein the pin has one of a circular shape or a polygonal shape on a cross-section, and wherein the pin holes and the chain groove have a shape corresponding to a shape of the pin.

6. The display device of claim 2, wherein the coupling portion comprises a first guide portion disposed adjacent to the one end, a second guide portion disposed adjacent to the other end, and a central portion disposed between the first guide portion and the second guide portion, wherein
a width of the central portion in the second direction is greater than a width of the first guide portion and a width of the second guide portion.

7. The display device of claim 6, wherein the bumps are respectively inserted between the adjacent central portions along a circumference of the roller.

8. The display device of claim 6, wherein the first guide portion and the second guide portion are in contact with a rear surface of the base portion, and wherein the central portion is not in contact with the rear surface.

9. The display device of claim 2, wherein the coupling portion comprises guide portions spaced apart from each other in the second direction, and central portions disposed between adjacent guide portions in the second direction,
wherein the bumps are arranged apart from each other along the second direction and along a circumference of the roller, and
the bumps are respectively inserted between adjacent central portions along the circumference of the roller.

10. The display device of claim 2, wherein when the roller rotates, the coupling portion disposed between the bumps rotates in the pin.

11. The display device of claim 1, wherein the chain units each comprise coupling portions each of which include a first guide portion, a second guide portion, and a central portion disposed between the first guide portion and the second guide portion, and in which a chain groove is defined, and a pin which is inserted into the chain groove, wherein
the coupling portions are spaced apart from each other along the second direction, and the pin is exposed between adjacent coupling portions in the second direction.

12. The display device of claim 11, wherein a width of each of the bumps in the second direction is equal to or smaller than a width of the central portion in the second direction.

13. The display device of claim 1, wherein when the roller rotates, a portion bent by the roller among the base portion, the display module overlapping the base portion, the first sidewall and the second sidewall is changeable.

14. The display device of claim 1, wherein the bumps have one of a triangular shape or a trapezoidal shape on a cross-section.

15. The display device of claim 1, wherein the base portion, the first sidewall, and the second sidewall are integral with each other.

16. The display device of claim 1, wherein the display module comprises:
an electronic panel including a display panel configured to supply an image, an input sensing portion configured to sense an external input, and an anti-reflective layer disposed on the input sensing portion;
an impact-absorbing layer disposed on the electronic panel;
a window disposed on the impact-absorbing layer; and
a panel protection layer disposed under the electronic panel.

17. The display device of claim 16, wherein when the roller rotates to change from a first mode to a second mode, an area of the display module increases, and
a number of chain units disposed adjacent to the window in the second mode is greater than a number of chain units disposed adjacent to the window in the first mode.

18. The display device of claim 1, further comprising a flexible circuit board connected to an end of the display module and a driving chip connected to the flexible circuit board,
wherein a portion of the end of the display module to which the flexible circuit board of the display module is connected is bent to face a rear surface of the plate.

19. The display device of claim 1, further comprising an adhesive layer disposed between the display module and the plate,
wherein the adhesive layer is one of a pressure sensitive adhesive (PSA) or an optically clear adhesive (OCA).

20. The display device of claim 1, wherein the plate comprises stainless steel.
